(19) United States
(12) Patent Application Publication
(10) Pub. No.: US 2011/0267779 A1
(43) Pub. Date: Nov. 3, 2011

(54) LED LIGHTING SYSTEM WITH A THERMAL CONNECTOR

(76) Inventors: Eran PLONSKI, Montreal (CA); Sharath KUMAR, Laval (CA); Eihab BAQUI, Brossard (CA)

(21) Appl. No.: 13/038,945

(22) Filed: Mar. 2, 2011

Related U.S. Application Data
(60) Provisional application No. 61/309,998, filed on Mar. 3, 2010.

(51) Int. Cl. H05K 7/20

(52) U.S. Cl. 361/709

(57) ABSTRACT

There is described an LED lighting system comprising: at least one light emitting diode (LED); a heat sink thermally connected to the at least one LED for dissipating heat generated by the at least one LED; an electrical connector for electrically connecting the LED lighting system to a power source; and a thermal insulating connector having a first end connected to the heat sink and a second end connected to the electrical connector, the thermal connector comprising a chamber adapted to receive an electronic circuit therein, the electronic circuit being operatively connected to the at least one LED and the electrical connector.

### CROSS-REFERENCE TO RELATED APPLICATIONS

This application claims priority under 35 U.S.C. §119(e) from U.S. Provisional Patent Application No. 61/309,998, filed on Mar. 3, 2010, the contents of which are hereby incorporated by reference.

### TECHNICAL FIELD

The present invention relates to the field of LED lighting systems, and particularly to thermal protection of electronic circuitry in LED lighting systems.

### BACKGROUND

Light emitting diode (LED) lighting systems usually include a heat sink in order to cool heat generating LEDs. A heat sink cools the device by absorbing and dissipating generated heat and is made of a thermal conductive material. The transfer of heat is improved by providing the heat sink with a specific shape, intended to create greater surface area and an improved thermal flow.

When LED lighting systems comprise embedded electronic circuitry, such as an electrical power converter circuit, the electronic circuitry is usually positioned in a cavity inside the heat sink. As a result, the electronic circuitry can be exposed to a high temperature environment when the LEDs are in operation, which can damage or shorten the lifetime of an electronic circuit.

Therefore, there is a need for thermally protecting embedded electronic circuitry in an LED lighting system.

### SUMMARY

According to a first broad aspect, there is provided an LED lighting system comprising: at least one light emitting diode (LED); a heat sink thermally connected to the at least one LED for dissipating heat generated by the at least one LED; an electrical connector for electrically connecting the LED lighting system to a power source; and a thermal insulating connector having a first end connected to the heat sink and a second end connected to the electrical connector, the thermal connector comprising a chamber adapted to receive an electronic circuit therein, the electronic circuit being operatively connected to the at least one LED and the electrical connector.

### BRIEF DESCRIPTION OF THE DRAWINGS

Further features and advantages of the present invention will become apparent from the following detailed description, taken in combination with the appended drawings, in which:

FIG. 1 is an exploded view of an LED lighting system comprising electronic circuitry embedded in a thermal connector, in accordance with an embodiment;

FIG. 2 is a top view of the thermal connector of the FIG. 1;

FIG. 3 is a front view of a T-shaped thermal connector provided with a chamber in the upper portion of the connector, in accordance with an embodiment;

FIG. 4 is a front view of a T-shaped thermal connector provided with a chamber in the lower portion of the connector, in accordance with an embodiment;

FIG. 5a is a front view of a bayonet-type electrical connector, in accordance with an embodiment;

FIG. 5b is a front view of a GU-type electrical connector, in accordance with an embodiment; and

FIG. 5c is a front view of an MR-type electrical connector, in accordance with an embodiment.

It will be noted that throughout the appended drawings, like features are identified by like reference numerals.

### DETAILED DESCRIPTION

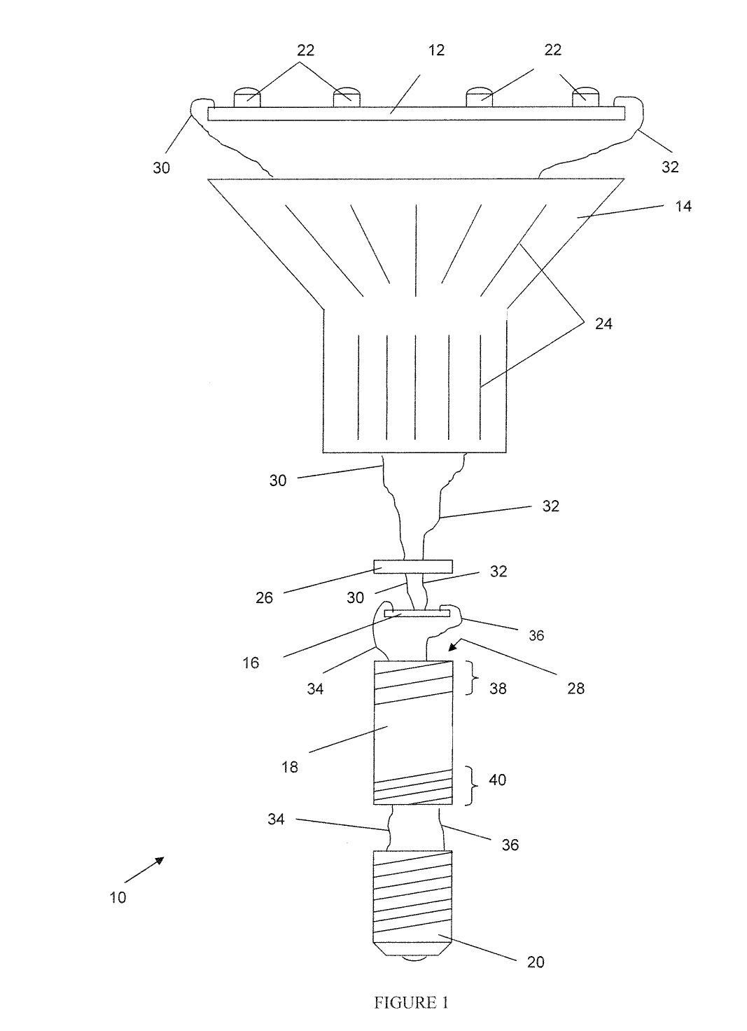

FIG. 1 illustrates one embodiment of an LED lighting system 10 which comprises an LED board 12, a heat sink 14, an embedded electronics circuit 16, a thermal insulating connector 18, and an electrical connector 20. The LED board 12 has a plurality of LEDs 22 positioned on its top surface. The LED board 12 also comprises electrical connections on its top surface to electrically connect the LED 22 to a source of power. The heat sink 14 is designed to receive the LED board 12 on its top surface and the heat radiating fins 24 are designed to remove the heat generated by the LEDs 22 from the LED board 12. Any mechanical means can be used to removably or permanently attach the LED board to the top surface of the heat sink 14. For example, screws can be used to removably secure the LED board 12. Alternatively, the LED board 12 can be welded to the heat sink 14 in order to be permanently attached thereto. The LED board 12 can also be bonded to the heat sink 14 by thermal tape which increases the thermal communication between the LED board 12 and the heat sink 14 and increases the cooling of the LED board 12. Alternatively, a thermal paste can be used to bond the LED board 12 to the heat sink 14. A thermal conductive plate made of heat conductive material such as graphite, for example, can also be inserted between the LED board 12 and the heat sink 14 in order to improve the heat transfer between the two.

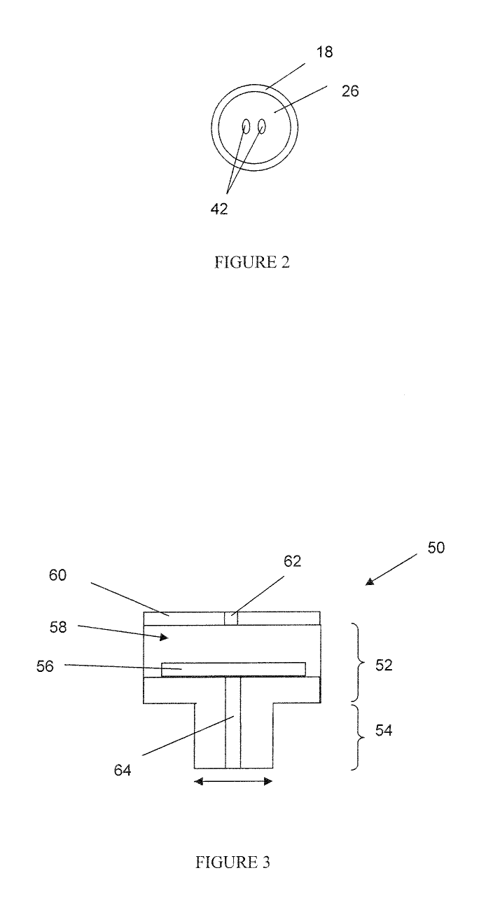

The thermal connector 18 has a chamber 28 of which the shape and size are adapted to receive the circuit 16. The thermal connector 18 is made of any thermal insulating material such as plastic, polycarbonate, or the like. A cover 26 also made of a thermal insulating material is used to seal the chamber 28 once the circuit is inserted into the chamber 28. The thermal connector 18 and the thermal cover 26 protects the enclosed circuit 26 from the heat emitted by the heat sink 14. The cover 26 is provided with at least one hole 42 so that electrical cables 30 and 32 connect the circuit 16 to the LEDs 22 of the LED board 12, as illustrated in FIGS. 1 and 2.

Once the circuit 16 is enclosed in the chamber 28 and the cover 26 is positioned on top of the thermal connector 18, the thermal connector 18 is attached to the heat sink 14 and the electrical connector 20. The thermal connector 18 is provided with a thread 38 on its upper outer surface. The heat sink comprises a threaded aperture on its lower inner surface. The dimensions of the aperture are adapted to receive the thermal connector 18 for threading into the heat sink 14. The thermal connector 18 also comprises a second thread 40 on its lower outer surface. The electrical connector 20 comprises a threaded aperture of which the thread corresponds to the second thread 40 of the thermal connector 18. The thermal connector 18 is then screwed into the electrical connector 20.

The circuit 16 is connected to the electrical connector 20 via cables 34 and 36. The bottom part of the thermal connector 18 is provided with at least one aperture adapted to receive the cables 34 and 36. The electrical base connector 20 receives electric power from an external power source and transmits it to the LEDs 22 via cables 30, 32, 34, and 36, and the circuit 16.

While the present description refers to four LEDs 22, it should be understood that the LED lighting system 10 can comprise one or more LEDs. The LEDs can be white LEDs or colored LEDs. The system 10 can be an RGB system comprising red, green, and blue LEDs in order to produce a white light.

In one embodiment, the thermal insulating material is also an electrical insulating material. As a result, the thermal connector 18 and the cover 26 form an electrical insulating barrier protecting the enclosed circuit 16.

In one embodiment, the circuit 16 is fixedly attached in the chamber 28 using screws or clamps, for example. Alternatively, any adhesive can be used to attach the circuit 16 in the chamber 28. It should be understood that any mechanical means can be used to removably or permanently secure the circuit 16 in the chamber 28.

The circuit 16 can be any type of embedded circuit used in LED lighting systems, such as an electric circuit, an electronic circuit, a microprocessor, and the like. The circuit 16 can be an electrical power converter for converting a 110V ac input into a 12V dc output, for example. Electronic controllers represent another example of embedded circuit 16. For example, the circuit 16 can be a DMX network protocol controller, a dimmer circuit, etc.

While the chamber 28 extends from the top surface of the thermal connector 18, it should be understood that the chamber could be located elsewhere within the connector 18. For example, the chamber 28 could be located in the lower portion of the connector 18 and connected to the bottom surface of the thermal connector 18.

In one embodiment, a lens or lens assembly is positioned on top of LED board 12. The lens can be secured to the heat sink using any mechanical means such as clamps, screws, etc.

While the thermal connector 18 is attached to the bottom surface of the heat sink 14, it should be understood that the thermal connector 18 could be secured on another surface of the heat sink 14, such as on the lateral outer surface.

Any mechanical means can be used for fastening the thermal connector 18 to the heat sink 14 and the electrical connector 20. For example, the thermal connector 18 can be screwed to the heat sink 14, and the thermal connector 18 and the electrical connector 20 are secured together via a bayonet mechanism. The bayonet mechanism comprises pins located on the lateral outer surface of the thermal connector 18. The pins are inserted into slots present on the lateral surface of the electrical connector 20. A spring present in the electrical connector 20 can be used to apply a clamping force. Alternatively, an adhesive can be used for securing the thermal connector 18 to the heat sink 14 and the electrical connector 20. In this case, the bottom surface of the heat sink 14 and the top surface of the electrical connector 20 can be planar surfaces with no hole and the thermal connector is glued to these surfaces.

While FIG. 1 refers to a cylindrical thermal connector 18, it should be understood that the thermal connector can have any shape. FIG. 3 illustrates one embodiment of a T-shaped thermal connector 50 having a first section 52 and a second section 54. The dimensions of the first section 52 are adapted to the dimensions of the circuit 56 while the size of the second section 54 is adapted to that of the electrical connector to which the thermal connector 50 is to be secured. The connector 50 comprises a chamber 58 in the first section for receiving the electronic circuit 56. A cover 60 closes the chamber 58 and protects the circuit 56 from the heat emitted by the heat sink to which the first section 52 of the thermal connector 52 is secured. The cover is provided with an aperture 62 to allow an electrical cable to connect the circuit 56 to the LEDs. The thermal connector 50 is provided with an aperture 64 which connects the chamber 58 to the bottom surface of the second section 54 and which allows electrical cables to connect the circuit 56 to the electrical connector.

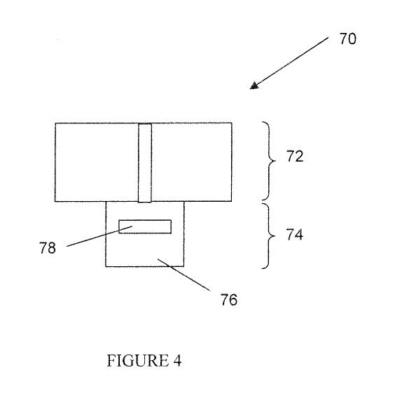

FIG. 4 illustrates another embodiment of a T-shaped connector 70 having a top section 72 and a bottom section 74. The bottom section 74 is provided with a chamber in which an electronic circuit 78 is inserted. As the thermal connector 70 comprises no cover, the chamber 76 is laid opened. The circuit 78 can be fixedly attached within the chamber 76. Alternatively, the tension in the electrical cables which connect the circuit 78 to the LEDs 22 is sufficient to maintain the circuit 78 in position within the chamber 76.

In one embodiment, the thermal insulating connector 70 is provided with a cover adapted to enclose the circuit 78 within the chamber 76.

In one embodiment, the LED lighting system 10 is a retrofit lighting system which can be connected to already existing electrical installations. For example, the LED lighting system 10 can be a retrofit lamp used in replacement of a usual light bulb. Light bulbs require a 110V-240V ac electrical current and therefore the electrical installations that receive the light bulb are adapted to provide a 110V-240V ac electrical current to the light bulb. If an LED lighting system is used as a retrofit light bulb, the voltage is converted since LEDs usually require a dc voltage. In this case, the embedded circuit can be an electrical power converter for converting a 110V-240V ac input into a 12V dc output, for example.

It should be understood that the LED lighting system can be any type of lamp, such as a mirrored reflected (MR) lamp or a parabolic aluminized reflector (PAR) lamp, for example.

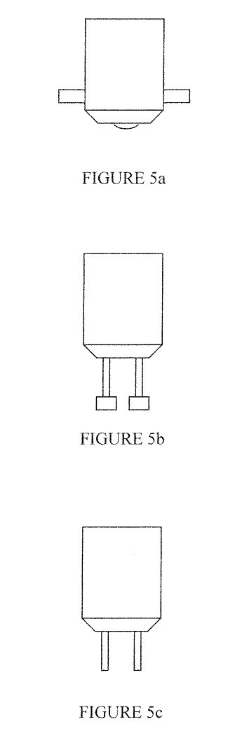

While the electrical connector 20 illustrated in FIG. 1 is an Edison screw type connector, FIGS. 5a-c illustrate other types of electrical connectors that can be used in the LED lighting system. FIG. 5a illustrates a bayonet-type electrical connector while FIGS. 5b and 5c illustrate a GU-type electrical connector and an MR-type electrical connector, respectively.

The embodiments of the invention described above are intended to be exemplary only. The scope of the invention is therefore intended to be limited solely by the scope of the appended claims.

I/we claim:

1. An LED lighting system comprising:
at least one light emitting diode (LED);
a heat sink thermally connected to said at least one LED for dissipating heat generated by said at least one LED;
an electrical connector for electrically connecting said LED lighting system to a power source; and
a thermal insulating connector having a first end connected to said heat sink and a second end connected to said electrical connector, said thermal connector comprising a chamber adapted to receive an electronic circuit therein, said electronic circuit being operatively connected to said at least one LED and said electrical connector.

2. The LED lighting system as claimed in claim 1, wherein said thermal insulating connector is made of a thermal and electrical insulating material.
